(19) United States
(12) Patent Application Publication
(10) Pub. No.: US 2008/0105286 A1
(43) Pub. Date: May 8, 2008

(54) Substrate Treatment Apparatus

(75) Inventors: Hiroshi Kizawa, Asakuchi-gun (JP); Takahiro Koga, Asakuchi-gun (JP); Katsuyoshi Nakatsukasa, Asakuchi-gun (JP); Kazuhisa Ogasawara, Asakuchi-gun (JP); Hiroshi Yamaguchi, Asakuchi-gun (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: S.E.S. CO., LTD., Tokyo (JP)

(21) Appl. No.: 11/576,854

(22) PCT Filed: May 23, 2005
(86) PCT No.: PCT/JP05/09322

§ 371 Date: Jan. 7, 2008

(30) Foreign Application Priority Data
Oct. 7, 2004 (JP) 2004-295337

(51) Int. Cl. B08B 3/04; H01L 21/304; B08B 3/12

(52) U.S. Cl. 134/56 R

(57) ABSTRACT

A substrate treatment apparatus is provided with a treatment bath (1) composed of a bottomed container which is surrounded by side walls (2b-2e) on the four sides and is open at the top, and first and second supplying nozzle tubes (10a-10d) which supply the treatment bath (1) with a treatment solution. The first and second supplying nozzle tubes (10a-10d) are composed of supplying nozzle tubes having a plurality of jetting ports (11) arranged on one line at prescribed intervals on each side plane in a longitudinal direction of the hollow tube-shaped body. The jetting ports of the first supplying nozzle tubes (10b, 10d) among the nozzle tubes are inclined diagonally downward at a prescribed angle from the horizontal direction, the jetting ports of the second supplying nozzle tubes (10a, 10c) are inclined diagonally upward at a prescribed angle from the horizontal direction, and the supplying nozzle tubes are arranged substantially horizontal at prescribed intervals on one side wall plane (2b) of the treatment bath (1). Stagnation of the treatment solution in the treatment bath is eliminated, uniform substrate treatment is made possible and furthermore, particle removal is facilitated.

### TECHNICAL FIELD

The present invention relates to a substrate treatment apparatus for treating semiconductor wafers, liquid crystal display substrates, recording disk substrates, mask substrates, and various other types of substrates.

### RELATED ART

Various types of substrate manufacturing processes, e.g. a semiconductor manufacturing process, include chemical treatment with various types of chemical liquids and cleansing treatment with a rinse liquid to eliminate contaminants attached to the surfaces of a semiconductor wafer (hereinafter referred to as “wafer”) or remove unnecessary oxide or resist films, for example.

To provide such treatment processes in a single treatment bath, a plurality of wafers are placed horizontally upright in the treatment bath. Chemical and rinse liquids are supplied from the bottom of the treatment bath, and circulated in the bath, thereby providing chemical and cleansing treatments.

When the flow of the supplied chemical and rinse liquids stagnates or is disturbed in the bath, contaminants and other unnecessary materials attached to the wafer surfaces cannot be removed, and even unnecessary materials once removed may adhere to the wafer surfaces again.

In order to cope with this problem, surface treatment apparatuses capable of preventing the stagnation and disturbed flow of a treatment solution in a bath have been developed, widely used, and disclosed in patent documents (see Patent Documents 1, 2, and 3, for example).

FIG. 9 is a sectional view showing an example of a treatment bath provided in a known substrate treatment apparatus. Illustrating the substrate treatment apparatus shown in FIG. 9, FIG. 10A shows flow paths developed in the treatment bath, and FIG. 10B shows a substrate that has been treated with this substrate treatment apparatus.

Referring to FIGS. 9 and 10, this treatment bath 20 includes: an inner bath 21 having four side walls in which a plurality of circle disk substrates W are placed upright at regular intervals and are immersed in a treatment solution so as to be treated; an outer bath (not shown) surrounding the periphery of the inner bath 21 so as to contain the treatment solution overflowed from the inner bath 21; and a plurality of supplying nozzle tubes 22a to 22e for supplying the treatment solution to the inner bath 21. The supplying nozzle tubes 22a to 22e have a plurality of jetting ports 22a′ to 22e′, respectively, on their respective side plane of the tube-shaped bodies.

The supplying nozzle tubes 22a to 22e are positioned at the center and both sides of a portion near the bottom 21a of the inner bath 21 and at portions near both inclined surfaces 21b in a way that they cut across the inside of the inner bath 21. The supplying nozzle tubes 22a to 22e eject the treatment solution toward the center of the substrates W to be treated. The treatment solution is circulated in the inner bath 21 so as to treat the surfaces of the substrates W.

Some surface treatment apparatuses are known to have a plurality of supplying nozzle tubes not on the bottom of their treatment baths but on their side wall planes (see, for example, Patent Document 1 below).

FIG. 11 is a sectional view of a treatment bath described in Patent Document 1 below.

This treatment bath 30 is provided with four supplying nozzle tubes 31a to 31d on the upper left, lower left, upper right, and lower right of the treatment bath. The respective supplying nozzle tubes are configured to be coupled to supply sources 33a to 33d of a treatment solution with valves 32a to 32d, respectively, therebetween.

The treatment solution from each of the supplying nozzle tubes 31a to 31d is supplied in respective prescribed directions toward a substrate W to be treated. Specifically, the supply comes from the supplying tube 31a to the upper left of the substrate W, from the supplying tube 31b to the lower left, from the supplying tube 31c to the upper right, and from the supplying tube 31d to the lower right in a prescribed order. Provided to the bottom of the treatment bath 30 is a drain outlet. This drain outlet is coupled to a drain treatment part 35 with a pipe via a valve 34.

Some other surface treatment apparatuses are known not simply to circulate a treatment solution but to make swirling currents in their treatment baths to provide surface treatment with the swirling currents (see, for example, Patent Document 2 below).

FIG. 12 is a sectional view showing a treatment bath described in Patent Document 2.

The whole wall of this treatment bath 40 has a corrugated spiral surface. Provided at a bottom area of the treatment bath 40 is a supply part of a treatment solution. The part has a structure with two supply ports 41 and 42 for directing the discharge of the treatment solution along the spiral. To the periphery of the supply ports 41 and 42, rectifying fins 43 and 44, respectively, are provided for controlling the discharge direction of the treatment solution.

The discharging force of the treatment solution supplied from each of the supply ports 41 and 42 actively generates swirling currents of the treatment solution flowing in a prescribed direction in a storage tank so as to provide surface treatment for a substrate to be treated.

Further, some surface treatment apparatuses are known to rotate a substrate to be treated, instead of making swirling currents in their treatment baths (see, for example, Patent Document 3 below).

### [Patent Document 1]

JP-A-2001-274133 (FIG. 3, paragraphs [0029], [0035] to [0038])

### [Patent Document 2]

JP-A-2003-282512 (FIG. 1, paragraphs [0022] to [0025])

### [Patent Document 3]

JP-A-2000-114233 (FIG. 3, paragraphs [0027] and [0028])

### DISCLOSURE OF THE INVENTION

### Problems to Be Solved

With the known treatment bath 20 shown in FIGS. 9 and 10, the treatment solution supplied from each of the supplying nozzle tubes 22a to 22e makes the water flows indicated by the arrows A to C in FIG. 10A so as to treat the surfaces of a substrate W to be treated.

Specifically, the jetting ports 22d′ and 22e′ of the supplying nozzle tubes 22d and 22e, respectively, provided to the inclined surfaces 21b make water flows that are swirling currents running through nearly the center of the substrate W which flow along the side wall planes of the inner bath 21 as shown by the arrow A. The jetting ports 22a′ and 22c′ provided to both ends of the bottom of the inner bath 21 make water flows toward the center of the substrate W (arrow B). The jetting ports 22b′ on the center of the bottom of the inner bath 21 make water hitting the bottom of the substrate W (arrow C).

However, it has been proven that the treatment bath 20 tends to disadvantageously cause stagnation of particles and reaction products at portions Wa to Wc near the periphery of the substrate W as shown in FIG. 10B, resulting in uneven concentration distribution of the treatment solution with poor uniformity.

Among others, the principal factors would include the following: the flow of water in the treatment bath veers to the right or left and fails to reach the upper portion Wa of the substrate W where desired cleansing effects are lost; the jetting ports are directed excessively upwardly to deviate from the flow of water in the lower part Wb of the substrate, thereby halving or wiping out cleansing effects; and the flow of water is swirling and stagnation is developed around its center in both side parts We of the substrate.

In the treatment bath 30 disclosed in Patent Document 1 and shown in FIG. 11, the supplying nozzle tubes 31a to 31d generate swirling currents in fixed directions regardless of which nozzle tube out of the four nozzle tubes is supplying the treatment solution, and never change the swirling flow directions. Therefore, the positions at which the treatment solution stagnates and particles concentrate are almost fixed, resulting in less advantageous effects than the apparatus shown in FIG. 10. Furthermore, since the supplying nozzle tubes 31a to 31d are provided on opposite side wall planes, it is difficult to make the supplying nozzle tubes on both sides supply the treatment solution at the same time. Accordingly, the supply amount of the treatment solution is limited, whereby the flow rate cannot be enhanced. Also, since the side walls of the treatment bath 30 have an almost even height, the treatment solution may be dispersed from the bath to the outside if an attempt is made to increase the supply amount and the flow rate of the solution. In addition, since the bottom of the treatment bath 30 is provided with a drain outlet, it is difficult to add an ultrasonic generator or other devices there.

The treatment bath 40 for generating swirling currents disclosed in Patent Document 2 and shown in FIG. 12 has a complicated structure. Another treatment bath as disclosed in Patent Document 3 in which substrates are rotated has a further complicated structure. Either case entails difficulties in use and maintenance, and is insufficient for coping with the above-mentioned issues.

In recent years, the development of such substrate treatment apparatuses capable of processing a large number of substrates with large diameters all at once has been required. For example, to treat a large number of substrates, for example, 50 or more substrates whose diameter is 300 mm or more, treatment baths tend to get larger. Such baths require higher flow rates. Moreover, eliminating foreign matter etc. with high specific gravities requires even higher flow rates.

On the other hand, securing such high flow rates requires a large amount of a treatment solution, thereby entailing high treatment costs.

The treatment solution in the above-described treatment baths is either circulated or made into swirling currents. Taking that into account, the inventors of the present invention have found that increasing the flow rate of the swirling currents and changing the directions of the currents at prescribed cycles can work as a solution to the above-mentioned issues and achieved the present invention.

Accordingly, the present invention is intended to provide a substrate treatment apparatus that is capable of eliminating stagnation of a treatment solution in a treatment bath and providing uniform substrate treatment.

In addition, the invention is intended to provide a substrate treatment apparatus that facilitates removal of particles.

### Means to Solve the Problems

(1) In view of the above-mentioned issues, a substrate treatment apparatus according to an aspect of the invention includes a treatment bath composed of a bottomed container which is surrounded by side walls on the four sides and is open at the top, and first and second supplying nozzle tubes which supply the treatment bath with a treatment solution.

The first and second supplying nozzle tubes are composed of hollow tube-shaped supplying nozzle tubes having a plurality of jetting ports arranged on one line at prescribed intervals on respective side plane thereof in the longitudinal direction. The jetting ports of the first supplying nozzle tubes are inclined diagonally downward at a prescribed angle from the horizontal direction. The jetting ports of the second supplying nozzle tubes are inclined diagonally upward at a prescribed angle from the horizontal direction. The supplying nozzle tubes are arranged nearly horizontal to each other at prescribed intervals on one side wall plane of the treatment bath.

(2) It is preferable that, in the aspect described in (1), the first and second supplying nozzle tubes be each composed of a plurality of supplying nozzle tubes and be alternatively placed at prescribed intervals.

(3) It is preferable that, in the aspect described in (1), the first and second supplying nozzle tubes be each composed of a plurality of supplying nozzle tubes, the first supplying nozzle tubes be placed above, and the second supplying nozzle tubes be placed below a horizontal line running through a central part of a substrate to be treated placed upright in the treatment bath.

(4) It is preferable that, in the aspect described in (1), the first and second supplying nozzle tubes be each composed of a plurality of supplying nozzle tubes, the first supplying nozzle tubes be placed below, and the second supplying nozzle tubes be placed above a horizontal line running through a central part of a substrate to be treated placed upright in the treatment bath.

(5) It is preferable that, in the aspect described in (1), the first and second supplying nozzle tubes be provided to the outside of one side wall plane of the treatment bath and the plurality of jetting ports on the side plane be in communication with the inside of the treatment bath.

(6) It is preferable that, in the aspect described in (1), the treatment bath include an inner bath having a taller side wall provided with the first and second supplying nozzle tubes and shorter side walls, and an outer bath surrounding the inner bath so as to contain the treatment solution overflowed from the inner bath.

(7) It is preferable that, in the aspect described in (6), each upper end surface of the shorter side walls be provided with a plurality of notches.

(8) It is preferable that, in the aspect described in any of (1) through (7), the treatment bath be provided with an ultrasonic generator at an outer wall surface of a bottom wall thereof.

(9) It is preferable that, in the aspect described in any of (1) through (7), the substrate treatment apparatus also include a controller that controls switching of supply of the treatment solution alternatively from the first and second supplying nozzle tubes to the treatment bath at prescribed time intervals and makes swirling currents in different directions in the treatment bath, and the swirling currents be used for substrate surface treatment.

(10) It is preferable that, in the aspect described in (8), the substrate treatment apparatus also include a controller that controls switching of supply of the treatment solution alternatively from the first and second supplying nozzle tubes to the treatment bath at prescribed time intervals, controls the ultrasonic generator, and makes swirling currents in different directions in the treatment bath, and an appropriate combination of the swirling currents and ultrasonic waves generated by the ultrasonic generator be used for substrate surface treatment.

(11) A substrate treatment apparatus according to another aspect of the invention includes a treatment bath composed of a bottomed container which is surrounded by side walls and is open at the top, and first and second supplying nozzle tubes which supply the treatment bath with a treatment solution.

The first and second supplying nozzle tubes are composed of hollow tube-shaped supplying nozzle tubes having a plurality of jetting ports arranged on at least one line at prescribed intervals on respective side plane thereof in the longitudinal direction, and are arranged nearly horizontal to each other at prescribed intervals on each of both opposite side wall planes of the treatment bath. The jetting ports of the first and second supplying nozzle tubes provided on one of the opposite side wall planes are inclined diagonally downward and upward, respectively, at a prescribed angle from the horizontal direction. The jetting ports of the first and second supplying nozzle tubes provided on the other of the opposite side wall planes are inclined diagonally upward and downward, respectively, at a prescribed angle from the horizontal direction.

(12) It is preferable that, in the aspect described in (11), the first and second supplying nozzle tubes be each composed of a plurality of supplying nozzle tubes and be alternatively placed at prescribed intervals.

(13) It is preferable that, in the aspect described in (11), the first and second supplying nozzle tubes be each composed of a plurality of supplying nozzle tubes, the first supplying nozzle tubes be placed above and below a horizontal line running through a central part of a substrate to be treated placed upright in the treatment bath on one and the other sides, respectively, and the second supplying nozzle tubes be placed below and above the horizontal line on one and the other sides, respectively.

(14) It is preferable that, in the aspect described in (11), the first and second supplying nozzle tubes be each composed of a plurality of supplying nozzle tubes, the first supplying nozzle tubes be placed below and above a horizontal line running through a central part of a substrate to be treated placed upright in the treatment bath on one and the other sides, respectively, and the second supplying nozzle tubes be placed above and below the horizontal line on one and the other sides, respectively.

(15) It is preferable that, in the aspect described in (11), the first and second supplying nozzle tubes be provided to the outside of both opposite side wall planes of the treatment bath and the plurality of jetting ports on the side plane be in communication with the inside of the treatment bath.

(16) It is preferable that, in the aspect described in (11), the treatment bath include an inner bath containing a substrate to be treated and an outer bath surrounding the inner bath so as to contain the treatment solution overflowed from the inner bath, and each upper end surface of the inner bath be provided with a plurality of notches.

(17) It is preferable that, in the aspect described in any of (11) through (16), the treatment bath be provided with an ultrasonic generator at an outer wall surface of a bottom wall thereof.

(18) It is preferable that, in the aspect described in any of (11) through (16), the substrate treatment apparatus also include a controller that controls switching of supply of the treatment solution alternatively from the first and second supplying nozzle tubes to the treatment bath at prescribed time intervals and makes swirling currents in different directions in the treatment bath, and the swirling currents be used for substrate surface treatment.

(19) It is preferable that, in the aspect described in (17), the substrate treatment apparatus also include a controller that controls switching of supply of the treatment solution alternatively from the first and second supplying nozzle tubes to the treatment bath at prescribed time intervals, controls the ultrasonic generator, and makes swirling currents in different directions in the treatment bath, and an appropriate combination of the swirling currents and ultrasonic waves generated by the ultrasonic generator be used for substrate surface treatment.

### ADVANTAGES OF THE INVENTION

The above-described features according to the present invention provide the following advantages. According to one aspect of the invention, the jetting ports of the first supplying nozzle tubes are inclined diagonally downward at a prescribed angle from the horizontal direction, and the jetting ports of the second supplying nozzle tubes are inclined diagonally upward at a prescribed angle from the horizontal direction. The supplying nozzle tubes are arranged horizontal to each other at prescribed intervals on one side wall plane of the treatment bath. Accordingly, supplying the treatment solution either from the first or second supplying nozzle tubes can make clockwise or counterclockwise swirling currents in the treatment bath.

Since simply providing the first and second supplying nozzle tubes to one side wall plane of the treatment bath can make swirling currents, it is possible to make a treatment bath economically with a simple structure unlike related-art bathes that have complicated structures.

According to a preferred aspect of the invention, increasing the number of the supplying nozzle tubes makes it easy to make swirling currents with different patterns in the treatment bath and increase their flow rates. Such swirling currents with increased flow rates make it possible to enhance treatment efficiency and thus treat a large number of substrates with a large diameter. Furthermore, it is possible to provide more preferable substrate treatment by changing the positions at which the first and second supplying nozzle tubes are provided.

According to a preferred aspect of the invention, providing the supplying nozzle tubes to the outside of the treatment bath can prevent the supplying nozzle tubes from hampering the flow of the treatment solution in the treatment bath and can reduce the volume of the treatment bath attributed to the absence of the supplying nozzle tubes in the treatment bath. It is therefore possible to save the treatment solution used for substrate treatment.

According to a preferred aspect of the invention, a shorter side wall inside the inner bath makes it possible to contain the treatment solution overflowed from the inner bath smoothly in the outer bath. Also, providing the supplying nozzle tubes to a taller side wall makes it possible to make swirling currents with small dispersal of the treatment liquid.

Specifically, swirling currents are directed from the taller side wall toward the shorter side wall. Here, the treatment solution overflowed from the inner bath mostly flows into the outer bath on the shorter-side wall plane, and hardly flows toward the taller side wall. Since thus the flow of the solution overflowed toward the outer bath is directed, it is possible to make the swirling currents more even with the flow of the currents from their rotation direction toward their axial direction restricted. Accordingly, it is possible to eliminate the difference between a substrate positioned at the center in the bath and another substrate positioned at the edge in the bath. Also, since the treatment liquid is prevented from flowing at the taller side wall part, it becomes easy to set up the treatment bath in consideration with drain treatment. Furthermore, by providing a plurality of notches on the upper end surface of the side wall, it is possible to evenly discharge the treatment solution overflowed from the inner bath without flow concentration, thereby avoiding the torrent of the treatment solution flowing into the outer bath at a single point and dispersal of the treatment liquid.

As for related-art apparatuses having the supplying nozzle tubes etc. at the bottom wall, if an ultrasonic generator is also provided to the bottom wall, the supplying nozzle tubes can cause transmission interference. Unlike such apparatuses, according to a preferred aspect of the invention, the supplying nozzle tubes are provided to the side wall plane, whereby the bottom wall can be used for fixing an ultrasonic generator. It is therefore possible to efficiently expose the substrate with ultrasonic waves.

This ultrasonic generator enables not only chemical treatment with a treatment solution but also physical treatment with ultrasonic vibration to a substrate to be treated in the treatment bath, thereby providing high-quality treatment.

According to a preferred aspect of the invention, supplying the treatment solution either from the first or second supplying nozzle tubes can make clockwise or counterclockwise swirling currents in the treatment bath.

Switching the supply of the treatment solution from the first and second supplying nozzle tubes at prescribed cycles makes it possible to alternately reverse the directions of the swirling currents of the treatment solution in the treatment bath.

As a result, the swirling currents can eliminate stagnation of the treatment solution in the treatment bath, thereby enabling efficient and uniform treatment of a substrate surface.

According to a preferred aspect of the invention, not only chemical treatment with a treatment solution but also physical treatment with ultrasonic vibration to a substrate to be treated can be provided. With a combination of these treatment methods, higher quality treatment can be provided.

According to another aspect of the invention, the jetting ports of the first and second supplying nozzle tubes provided on one side wall plane are inclined diagonally downward and upward, respectively, at a prescribed angle from the horizontal direction, and the jetting ports of the first and second supplying nozzle tubes provided on the other side wall plane are inclined diagonally upward and downward, respectively, at a prescribed angle from the horizontal direction. The supplying nozzle tubes are arranged horizontal to each other at prescribed intervals on each of both opposite side wall planes of the treatment bath. Accordingly, supplying the treatment solution either from one or the other supplying nozzle tubes on both side wall planes can make clockwise or counterclockwise swirling currents in the treatment bath.

According to another preferred aspect of the invention, increasing the number of the supplying nozzle tubes makes it easy to make swirling currents with different patterns in the treatment bath and increase their flow rates. Such swirling currents with increased flow rates make it possible to enhance treatment efficiency and thus treat a large number of substrates with a large diameter. Furthermore, it is possible to provide more preferable substrate treatment by changing the positions at which the first and second supplying nozzle tubes are provided.

According to another preferred aspect of the invention, providing the supplying nozzle tubes to the outside of the treatment bath can prevent the supplying nozzle tubes from hampering the flow of the treatment solution in the treatment bath and can reduce the volume of the treatment bath attributed to the absence of the supplying nozzle tubes in the treatment bath. It is therefore possible to save the treatment solution used for substrate treatment.

According to another preferred aspect of the invention, the treatment bath includes inner and outer baths and also includes a plurality of notches on the upper end surface of the inner bath. It is therefore possible to evenly discharge the treatment solution overflowed from the inner bath without flow concentration, thereby avoiding the torrent of the treatment solution flowing into the outer bath at a single point and dispersal of the treatment liquid when overflowed.

As for related-art apparatuses having the supplying nozzle tubes etc. at the bottom wall, if an ultrasonic generator is also provided to the bottom wall, the supplying nozzle tubes can cause transmission interference. Unlike such apparatuses, according to another preferred aspect of the invention, the supplying nozzle tubes are provided to the side wall plane, whereby the bottom wall can be used for fixing an ultrasonic generator.

This ultrasonic generator enables not only chemical treatment with a treatment solution but also physical treatment with ultrasonic vibration to a substrate to be treated in the treatment bath, thereby providing high-quality treatment.

According to another preferred aspect of the invention, supplying the treatment solution either from the first or second supplying nozzle tubes provided to both side wall planes can make clockwise or counterclockwise swirling currents in the treatment bath.

Switching the supply of the treatment solution from the first and second supplying nozzle tubes at prescribed cycles makes it possible to alternately reverse the directions of the swirling currents of the treatment solution in the treatment bath.

As a result, the swirling currents can eliminate stagnation of the treatment solution in the treatment bath, thereby enabling efficient and uniform treatment of a substrate surface.

According to another preferred aspect of the invention, not only chemical treatment with a treatment solution but also physical treatment with ultrasonic vibration to a substrate to be treated can be provided. With a combination of these treatment methods, higher quality treatment can be provided.

### BRIEF DESCRIPTION OF THE DRAWINGS

FIG. 1 Showing a treatment bath used in a substrate treatment apparatus according to a first embodiment of the present invention, FIG. 1A is a side sectional view and FIG. 1B is a top view.

FIG. 2 is a side view of supplying nozzle tubes disposed in the treatment bath shown in FIG. 1.

FIG. 3 shows an embodiment of directions in which the treatment solution supplied from each supplying nozzle tube is ejected.

FIG. 4 is a side view showing flows of the treatment solution in the treatment bath.

FIG. 5 shows modifications of directions in which the treatment solution supplied from each supplying nozzle tube is ejected.

FIG. 6 Showing a treatment bath used in a substrate treatment apparatus according to a second embodiment of the present invention, FIG. 6A is a side sectional view and FIG. 6B is a top view.

FIG. 7 shows an embodiment and a modification of directions in which the treatment solution supplied from each supplying nozzle tube is ejected.

FIG. 8 shows another modification of directions in which the treatment solution supplied from each supplying nozzle tube is ejected.

FIG. 9 is a sectional view of a treatment bath used in a known substrate treatment apparatus.

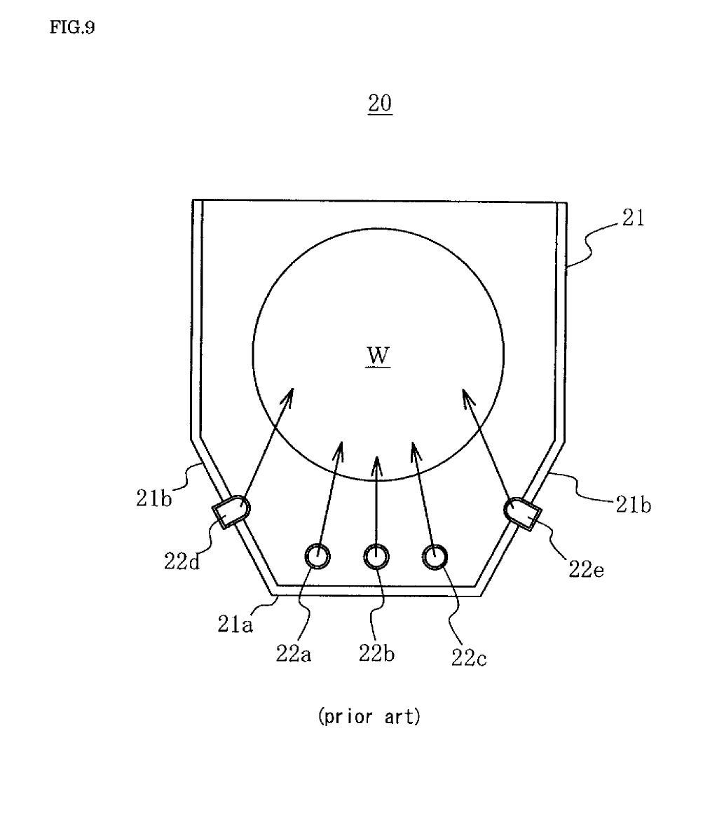

FIG. 10 Illustrating the substrate treatment apparatus shown in FIG. 9, FIG. 10A shows flow paths developed in the treatment bath, and FIG. 10B shows a substrate that has been treated with this substrate treatment apparatus.

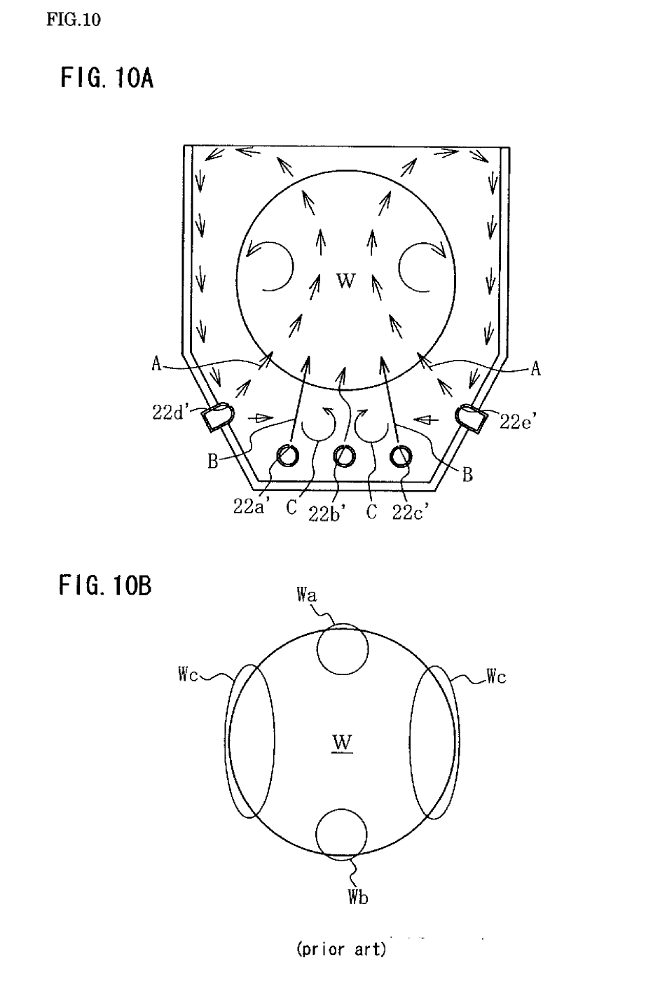

FIG. 11 is a sectional view of the treatment bath used in a related-art substrate treatment apparatus.

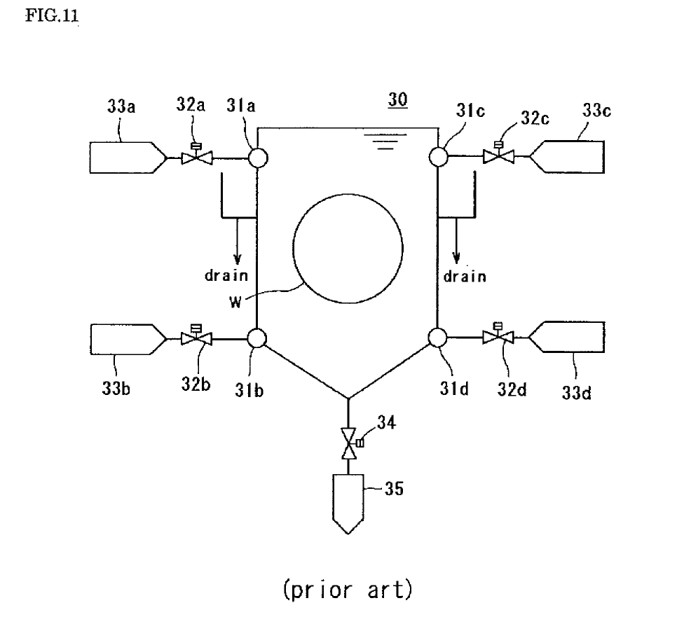

FIG. 12 is a sectional view of the treatment bath used in a related-art substrate treatment apparatus.

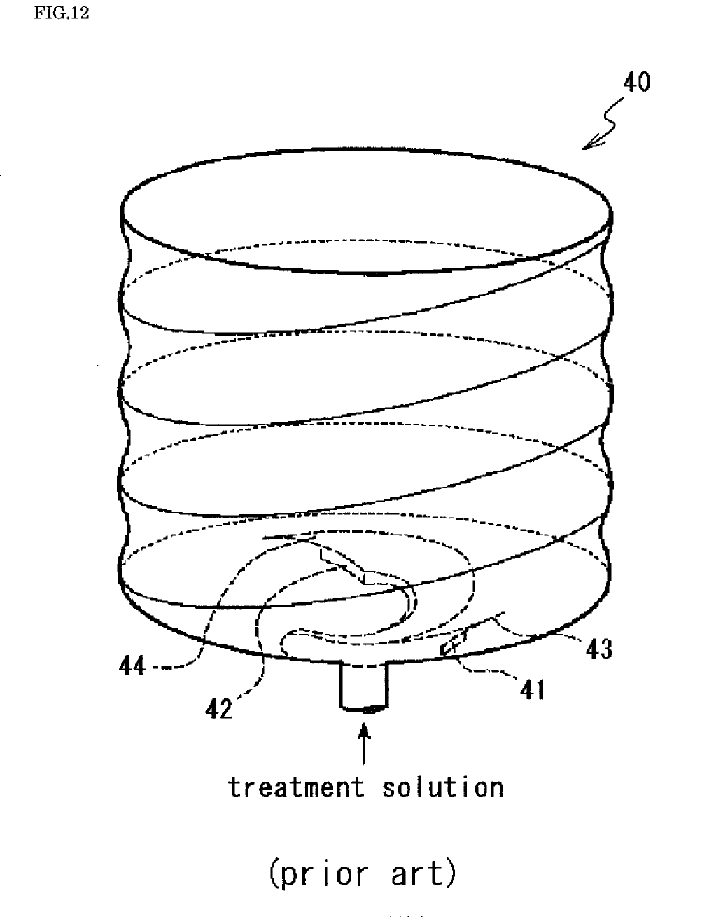

### REFERENCE NUMERALS

1, 1A: Treatment bath
2: Inner bath
2a: Bottom wall
2b to 2e: Side wall
3: Outer bath
4: (V-shaped) notch
5: Drain outlet
6: Container
7: Ultrasonic generator
10a to 10d: Supplying nozzle tube
10a′ to 10d′: Supplying nozzle tube
11: Jetting ports

### DESCRIPTION OF THE PREFERRED EMBODIMENTS

Preferred embodiments of the present invention will be described with reference to the accompanying drawings. It should be understood that the embodiments below are shown by way of illustrating a substrate treatment apparatus that embodies the technical concept of the invention, and are not intended to limit the invention to this substrate treatment apparatus. The invention is equally applicable to other embodiments within the spirit and scope of the claims appended hereto.

### First Embodiment

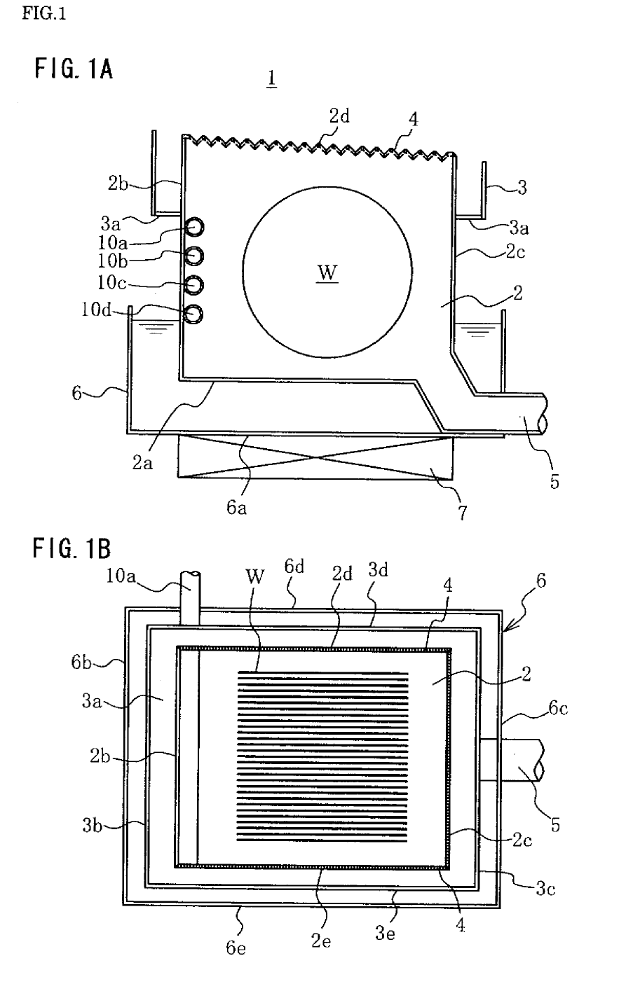

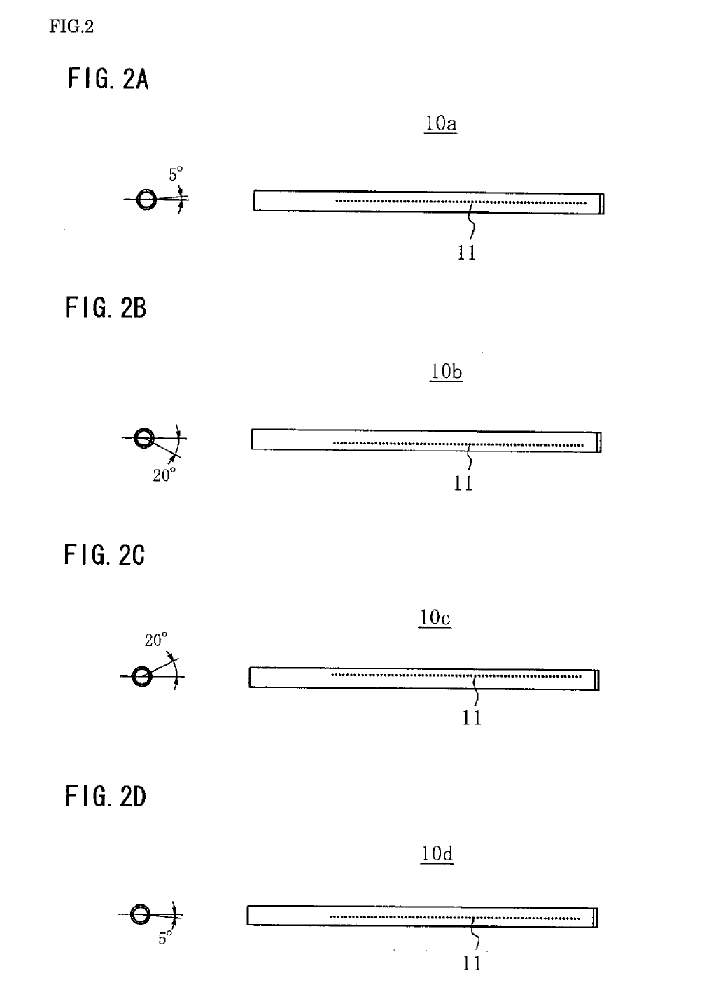

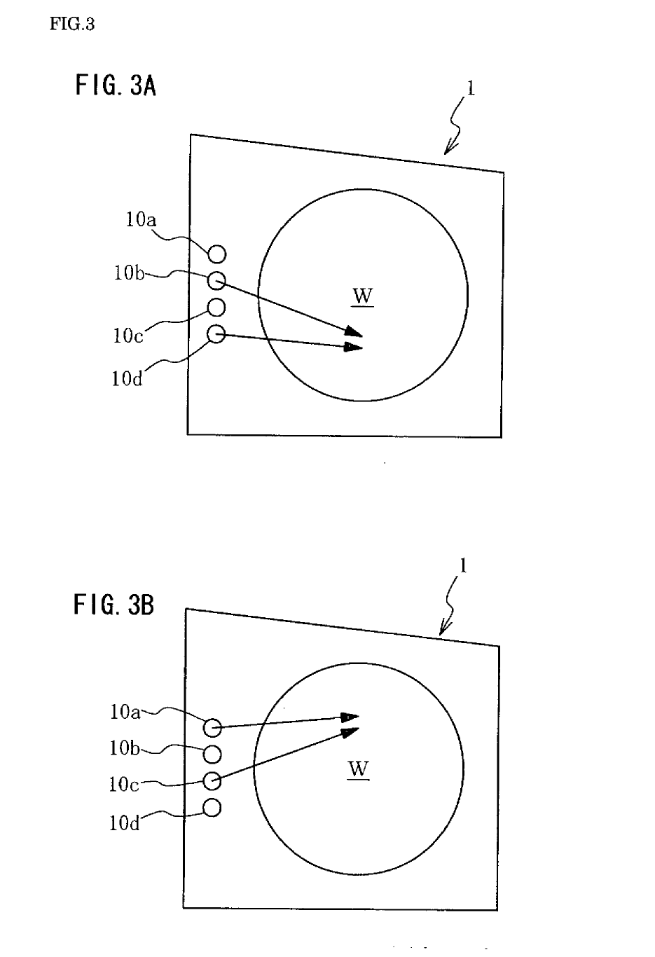

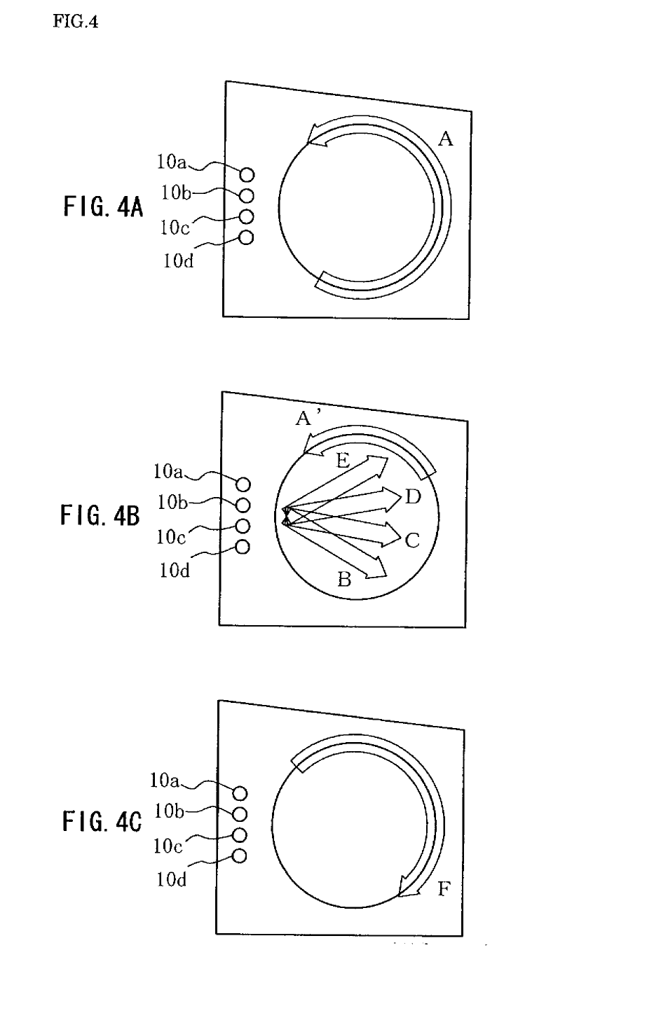

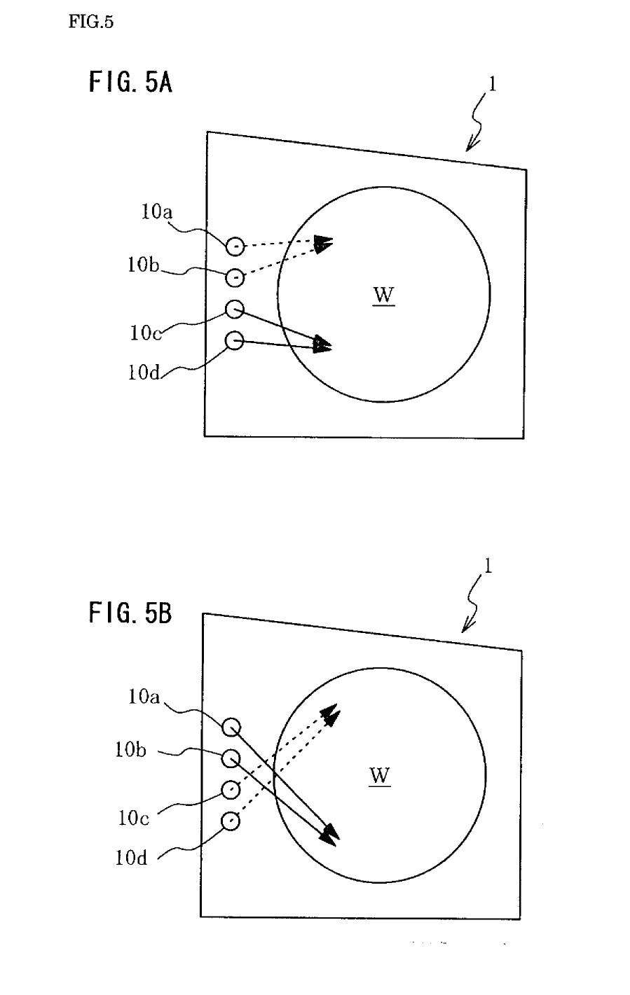

Showing a treatment bath used in a substrate treatment apparatus according to a first embodiment of the present invention, FIG. 1A is a side sectional view and FIG. 1B is a top view. FIG. 2 is a side view of supplying nozzle tubes disposed in the treatment bath shown in FIG. 1. FIG. 3 shows an embodiment of directions in which the treatment solution supplied from each supplying nozzle tube is ejected. FIG. 4 is a side view showing flows of the treatment solution in the treatment bath. FIG. 5 shows modifications of directions in which the treatment solution supplied from each supplying nozzle tube is ejected.

This substrate treatment apparatus includes a treatment bath 1. This single bath can be used for a series of surface treatment processes, including chemical and cleansing treatment, for semiconductor wafers, liquid crystal display substrates, recording disk substrates, mask substrates, and various other types of substrates. Representing various types of substrates, a semiconductor wafer (hereinafter referred to as the “wafer”) will be used in the following description. In the description below, a “treatment solution” collectively means chemical liquids for etching the surfaces of the wafer, for example, and cleansing liquids for cleansing the chemical liquids.

Referring to FIG. 1, the treatment bath 1 includes an inner bath 2 having a nearly square bottom wall 2a and upright side walls 2b to 2e on the four sides of the bottom wall 2a to form a boxy container that is open at the top. The treatment bath 1 also includes an outer bath 3 having a bottom wall 3a surrounded by side walls 3b to 3e provided with a prescribed distance around the periphery of the inner bath 2.

Among the side walls 2b to 2e, the side wall 2b provided with supplying nozzle tubes that will be described later is taller than the side wall 2c on the opposite side. The both ends of the side walls 2b and 2c on opposite sides are coupled by the side walls 2d and 2e. Accordingly, each upper end of the side walls 2d and 2e is inclined from the taller side wall 2b toward the shorter side wall 2c.

Among the side walls 2b to 2e, the upper ends of the side walls 2c to 2e other than the taller side wall 2b are provided with a plurality of V-shaped notches 4 as shown in FIG. 1B. The notches 4 enable the treatment solution overflowed from the inner bath 2 to be contained in the outer bath 3 without flow concentration, thereby avoiding dispersal to the outside.

Provided to a portion connecting the bottom wall 2a and the side wall plane 2c of the treatment bath 1 is a drain outlet 5. The drain outlet 5 is coupled to a drain treatment part (not shown) via a pipe.

The bottom 2a of the treatment bath 1 is provided with an ultrasonic generator 7 with a shallow boxy container 6 therebetween.

The boxy container 6 includes a bottom wall 6a that is a little larger than the bottom wall surfaces of the inner bath 2 and short side walls 6b to 6e. The container is fitted to the inner bath 2 with some space between the bottom wall surfaces of the inner bath 2 and the bottom of the container 6. The container 6 contains an ultrasonic transmitting medium, such as water. As the ultrasonic generator 7, a generator generating prescribed frequencies, e.g. 10 KHz to several MHz, is used.

By fitting the ultrasonic generator 7 to the bottom 2a of the treatment bath 1, ultrasonic waves emitted from the generator pass through water and the bottom 2a of the inner bath 2 to be transmitted to the treatment solution. The ultrasonic waves vibrate the treatment solution and act as a physical force on the surfaces of the wafer, thereby removing foreign matter, contaminants, and other particles attached to the surfaces of the wafer.

Provided inside the taller side wall 2b are a plurality of supplying nozzle tubes (four tubes in the drawing) 10a to 10d that are tube-shaped pipes arranged horizontal to each other at prescribed intervals. Referring to FIG. 2, the supplying nozzle tubes 10a to 10d have the same shape each provided with a plurality of treatment solution jetting ports 11 arranged on one line at prescribed pitches. For example, each of the supplying nozzle tubes 10a to 10d is a pipe having a diameter of 20 mm provided with holes having a diameter of 1.2 mm (jetting ports) at 5-mm intervals.

While the supplying nozzle tubes 10a to 10d are provided inside the side wall 2b in the present embodiment, they may be provided outside of the side wall 2b and only the jetting ports 11 may be in communication with the inner bath 2. This way, the supplying nozzle tubes 10a to 10d themselves do not intercept swirling currents made in the inner bath 2. Moreover, since it is unnecessary to spare space for providing the supplying nozzle tubes 10a to 10d in the inner bath 2, the volume of the inner bath 2 can be reduced, whereby the use amount of the treatment solution can be lowered.

The four supplying nozzle tubes 10a to 10d are arranged nearly horizontal to each other at prescribed intervals on the side wall 2b so that their jetting ports 11 are in prescribed directions. For example, the jetting ports 11 of the uppermost supplying nozzle tube 10a are inclined upward at an angle of 5° from the horizontal line as shown in FIG. 2A, the jetting ports 11 of the supplying nozzle tube 10b provided below the supplying nozzle tube 10a are inclined downward at an angle of 20° from the horizontal line as shown in FIG. 2B, the jetting ports 11 of the supplying nozzle tube 10c provided below the supplying nozzle tube 10b are inclined upward at an angle of 20° from the horizontal line as shown in FIG. 2C, and the jetting ports 11 of the lowermost supplying nozzle tube 10d are inclined downward at an angle of 5° from the horizontal line as shown in FIG. 2D, all of the tubes being arranged nearly horizontal to each other at prescribed intervals on the side wall 2b. Accordingly, of the supplying nozzle tubes 10a to 10d, two second supplying nozzle tubes 10a and 10c (the supplying nozzle tubes on odd numbered rows from the top in the drawing) whose jetting ports are inclined upward and two first supplying nozzle tubes 10b and 10d (the supplying nozzle tubes on even numbered rows from the top in the drawing) whose jetting ports are inclined downward are alternatively placed.

Consequently, of the four supplying nozzle tubes 10a to 10d, the second supplying nozzle tubes 10a and 10c on odd numbered rows have the jetting ports 11 inclined upward at prescribed angles from the horizontal line and the first supplying nozzle tubes 10b and 10d on even numbered rows have the jetting ports 11 inclined downward at prescribed angles from the horizontal line. Accordingly, by supplying the treatment solution either to the first or second supplying nozzle tubes, clockwise or counterclockwise swirling currents can be developed in the treatment bath 2.

Each of the supplying nozzle tubes 10a to 10d is coupled to a treatment solution supply source with a pipe via a valve. The treatment solution is supplied to each supplying nozzle tube by opening and closing of the valve (not shown) controlled by controlling means (not shown).

In this treatment bath, removal of contaminants attached to the wafer, etching of an oxide film, and separation of a resist film with various chemical liquids, and cleansing treatment with a rinse liquid are conducted.

Examples of the chemical liquids include: hydrofluoric acid for etching; ozone water in which ozone is dissolved in pure water, a mixture of ozone water and an additive containing bicarbonate ions such as sodium hydrogen carbonate, a liquid mixture of sulfuric acid and hydrogen peroxide, and a liquid mixture of sulfuric acid and ozone for separation of a resist film. As the rinse liquid, pure water is used. Accordingly, each supplying nozzle tube is coupled to the supply sources of these chemical and cleansing liquids, thereby supplying various types of treatment solutions.

Referring now to FIGS. 3 and 4, a method for supplying the treatment solution from each of the supplying nozzle tubes 10a to 10d into the treatment bath and treating the surfaces of the wafer with swirling currents will be described.

### I. Treatment with Supply of Treatment Solution

Of the four supplying nozzle tubes 10a to 10d, the two first supplying nozzle tubes 10b and 10d on even numbered rows and the two second supplying nozzle tubes 10a and 10c on odd numbered rows alternatively supply the treatment solution.

(i) Supply of Treatment Solution from First Supplying Nozzle Tubes 10b and 10d

First, as shown in FIG. 3A, the treatment solution is supplied from the two first supplying nozzle tubes 10b and 10d on even numbered rows into the inner bath 2. Accordingly, as the jetting ports 11 of the supplying nozzle tube 10b are inclined downward at an angle of 20° from the horizontal direction and the jetting ports 11 of the supplying nozzle tube 10d are inclined downward at an angle of 5° from the horizontal direction, a counterclockwise swirling current A is developed in the inner bath 2 as shown in FIG. 4A. The swirling current A has a prescribed flow rate, and this counterclockwise swirling current provides surface treatment for the wafer W.

(ii) Supply of Treatment Solution from Second Supplying Nozzle Tubes 10a and 10c

The supply of the treatment solution from the first supplying nozzle tubes 10b and 10d is stopped after 10 seconds, for example, and the supply of the treatment solution from the two second supplying nozzle tubes 10a and 10c on odd numbered rows starts thereafter. Accordingly, as the jetting ports 11 of the supplying nozzle tube 10a are inclined upward at an angle of 5° from the horizontal direction and the jetting ports 11 of the supplying nozzle tube 10c are inclined upward at an angle of 20° from the horizontal direction, the treatment solution supplied from the second supplying nozzle tubes 10a and 10c make the swirling current in the inner bath 2 into a clockwise swirling current (indicated by “F” in FIG. 4C).

Here, upward ejection from the second supplying nozzle tubes 10a and 10c is influenced by the counterclockwise swirling current A′ (remaining swirling current) made by the first supplying nozzle tubes 10b and 10d, thereby being turned into downward ejection (indicated by “B” in FIG. 4B) directly after the supply from the second supplying nozzle tubes 10a and 10c. After several seconds under this state, the flow of this ejection starts changing to be gradually restored to move upward (indicated by “C” to “E” in FIG. 4B), thereby making a clockwise swirling current F. Consequently, a stagnation portion (not shown) moves gradually as the flow changes gradually. As the stagnation portion to which particles tend to adhere is not fixed at one place, it is possible to prevent adhesion of such particles.

(iii) Switching Supply between (i) and (ii)

Subsequently, the supply of (i) and (ii) is switched so as to keep switching the clockwise swirling current F to the counterclockwise swirling current A, and further to the swirling current F for a prescribed period, for example, for one minute.

This method enables efficient cleansing without particles or reaction products adhered on the surfaces of the wafer W with the cleansing for one minute or so.

While, among the four supplying nozzle tubes 10a to 10d, the first and second supplying nozzle tubes are placed alternatively from the top to the bottom, their angles and order can be changed in order to make swirling currents in prescribed directions in the bath.

A substrate treatment apparatus will now be described in which the positions and directions of the first and second supplying nozzles provided to the treatment bath are changed. FIG. 5 shows modifications of directions in which each supplying nozzle tube is provided.

In the modification shown in FIG. 5A, the four supplying nozzle tubes 10a to 10d are arranged on the taller side wall 2b with their jetting ports changed to be disposed at the following angles.

The two supplying nozzle tubes 10a and 10b placed next to each other on the upper side in the inner bath are inclined upward at angles of 5° and 20°, respectively, from the horizontal line. Also, the two supplying nozzle tubes 10c and 10d placed next to each other on the lower side are inclined downward at angles of 20° and 5°, respectively, from the horizontal line. In other words, the two supplying nozzle tubes 10a and 10b placed next to each other on the upper side are the second supplying nozzle tubes, and the two supplying nozzle tubes 10c and 10d placed next to each other on the lower side are the first supplying nozzle tubes. The first and second supplying nozzle tubes respectively supply the treatment solution and develop swirling currents in the inner bath 2, thereby, for example, treating and cleansing the surfaces of the wafer W.

In the modification shown in FIG. 5B, the two supplying nozzle tubes 10a and 10b placed next to each other on the upper side in the inner bath are inclined downward at angles of 45° and 40°, respectively, from the horizontal line. Also, the two supplying nozzle tubes 10c and 10d placed next to each other on the lower side are inclined upward at angles of 40° and 45°, respectively, from the horizontal line. In other words, the two supplying nozzle tubes 10a and 10b placed next to each other on the upper side are the first supplying nozzle tubes, and the two supplying nozzle tubes 10c and 10d placed next to each other on the lower side are the second supplying nozzle tubes. The first and second supplying nozzle tubes respectively supply the treatment solution and develop swirling currents in the inner bath 2, thereby, for example, treating and cleansing the surfaces of the wafer W.

It should be understood that the number of the supplying nozzle tubes and the angles at which their jetting ports are provided are not limited to those described above, and any numbers and angles can be selected.

### II. Treatment with Ultrasonic Waves

The surface treatment for the substrate using ultrasonic waves will now be described.

This treatment starts with turning on the ultrasonic generator 7. Then, ultrasonic waves emitted by this generator 7 pass through water in the container 6 and the bottom 2a of the inner bath 2 to be transmitted to the treatment solution, thereby vibrating the treatment solution. This vibration of the treatment solution provides treatment by means of a physical force on the surfaces of the wafer W. The ultrasonic treatment used in the present embodiment is preferably conducted at the same time as the above-described process I in the last cleansing process after the completion of treatment for eliminating foreign matter, contaminants, and other particles attached to the wafer W by supplying ammonia and hydrogen peroxide to the treatment bath and of treatment with various types of chemical liquids.

The above-described treatment enables physical treatment with ultrasonic vibration in addition to chemical treatment with a treatment solution. With a combination of these treatment methods, higher quality substrate treatment can be provided.

### Second Embodiment

While the substrate treatment apparatus according to the first embodiment is provided with the plurality of the supplying nozzle tubes on one side of the inner bath, the plurality of supplying nozzle tubes may be provided to both opposite side walls.

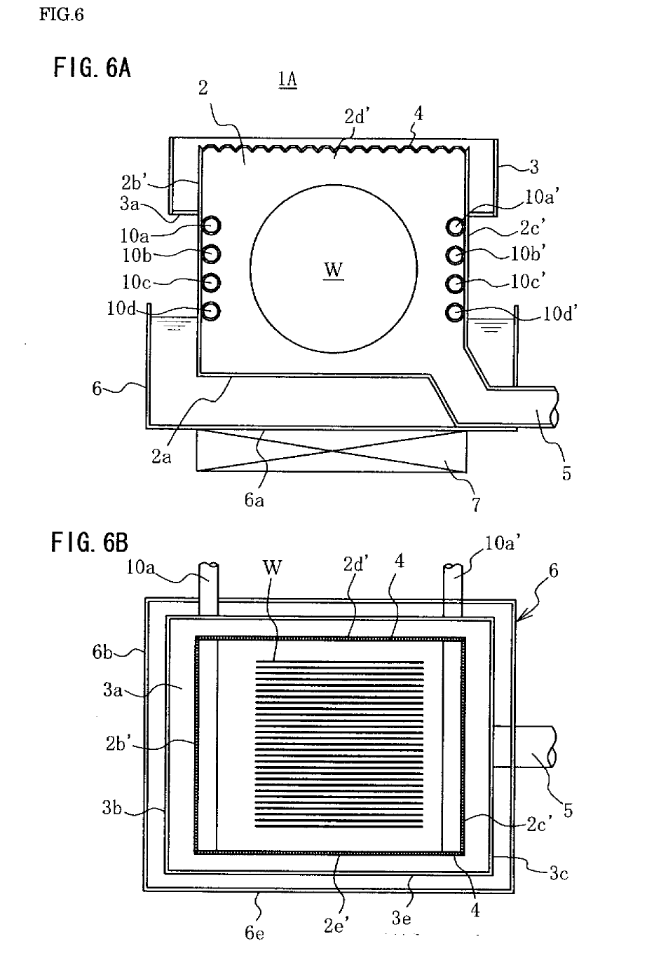

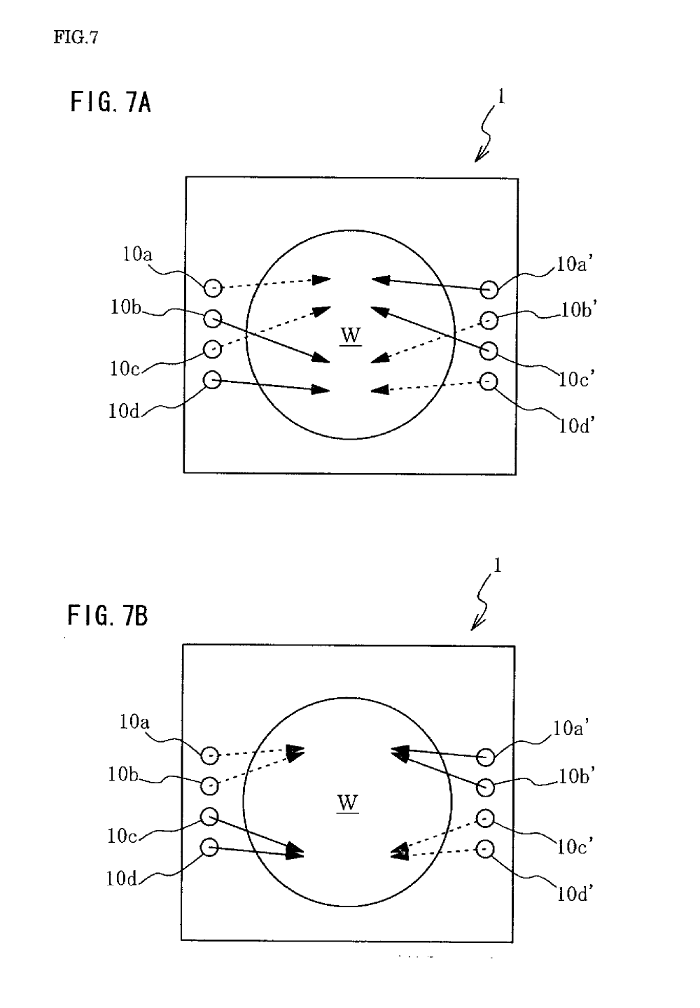

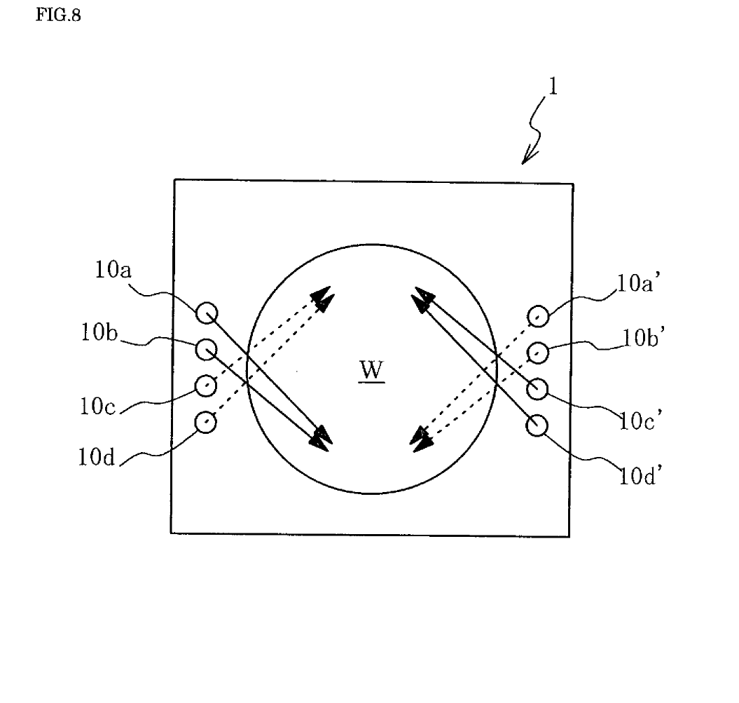

Showing a treatment bath used in a substrate treatment apparatus according to a second embodiment of the present invention, FIG. 6A is a side sectional view and FIG. 6B is a top view. FIGS. 7 and 8 illustrate directions in which the treatment solution supplied from each supplying nozzle tube is ejected.

This treatment bath 1A have features common to the treatment bath 1 in the first embodiment. Like numerals indicate like elements in the two embodiments and thus repeated description will be omitted. The description of the second embodiment will mainly focus on its features differing from the first embodiment.

In the treatment bath 1A, as shown in FIG. 6, each of the side walls 2b′ to 2e′ forming the inner bath 2 has an even height and is orthogonal to the surface of a wafer W accommodated in the inner bath 2. Each of the opposite side walls 2b′ and 2c′ is provided with a plurality of supplying nozzle tubes (four tubes each in the drawing) 10a to 10d and 10a′ to 10d′. The supplying nozzle tubes 10a to 10d and 10a′ to 10d′ provided to each of the side walls 2b′ and 2c′ are arranged so that their jetting ports are directed inwardly of the inner bath in prescribed directions. For example, as shown in FIG. 7A, the two supplying nozzle tubes 10a and 10c on odd numbered rows are inclined upward at angles of 5° and 20°, respectively, from the horizontal direction, and the supplying nozzle tubes 10b and 10d on even numbered rows are inclined downward at angles of 20° and 5°, respectively, from the horizontal direction on one opposite side wall 2b′. In the same manner, the two supplying nozzle tubes 10a′ and 10c′ on odd numbered rows are inclined upward at angles of 5° and 20°, respectively, from the horizontal direction, and the two supplying nozzle tubes 10b′ and 10d′ on even numbered rows are inclined downward at angles of 20° and 5°, respectively, from the horizontal direction on the other opposite side wall 2c′.

Since the four supplying nozzle tubes 10a to 10d and 10a′ to 10d′ are provided face-to-face with each other to the side walls 2b′ and 2c′, respectively, with their respective jetting ports set at the above-mentioned angles, each of the four supplying nozzle tubes 10a to 10d and 10a′ to 10d′ are symmetric to the vertical median line of the opposite side walls.

For example, among the four supplying nozzle tubes 10a to 10d and 10a′ to 10d′ on the side walls 2b′ and 2c′, respectively, as shown in FIG. 7A, the two supplying nozzle tubes 10b and 10d on even numbered rows provided to the side wall 2b′ and the two supplying nozzle tubes 10a′ and 10c′ on odd numbered rows provided to the side wall 2c′ are first supplying nozzle tubes having a synchronized timing for supplying the treatment solution, and the two supplying nozzle tubes 10a and 10c on odd numbered rows provided to the side wall 2b′ and the two supplying nozzle tubes 10b′ and 10d′ on even numbered rows provided to the side wall 2c′ are second supplying nozzle tubes having a synchronized timing for supplying the treatment solution, thereby developing swirling currents in the inner bath 2. Specifically, for example, the treatment solution is first supplied from the second supplying nozzle tubes 10a, 10c, 10b′, and 10d′ simultaneously for a prescribed period of time so as to make a clockwise swirling current in the inner bath. After the prescribed period of time, the supply from the second supplying nozzle tubes is stopped, and the treatment solution is then supplied from the first supplying nozzle tubes 10b, 10d, 10a′, and 10c′ simultaneously so as to make a counterclockwise swirling current in the inner bath. By switching the above-described supplying nozzle tubes for a plurality of times, desirable treatment for the wafer W can be provided. In the above-mentioned manner, the flow changes gradually as in the first embodiment, whereby a stagnation portion to which particles tend to adhere moves gradually. As the stagnation portion is not fixed at one place, it is possible to prevent adhesion of such particles.

In the present embodiment, the supplying nozzle tubes and the angles to which the treatment solution is supplied are not limited to the above description, and can be changed in various ways. Modifications of the supplying nozzle tubes provided to the substrate treatment apparatus in the present embodiment will now be described.

In the embodiment shown in FIG. 7B, the two supplying nozzle tubes 10a and 10b on the upper side are inclined upward at angles of 5° and 20°, respectively, from the horizontal direction, and the supplying nozzle tubes 10c and 10d on the lower side are inclined downward at angles of 20° and 5°, respectively, from the horizontal direction on one opposite side wall 2b′. In the same manner on the other opposite side wall 2c′, the two supplying nozzle tubes 10a′ and 10b′ on the upper side are inclined upward at angles of 5° and 20°, respectively, from the horizontal direction, and the two supplying nozzle tubes 10c′ and 10d′ on the lower side are inclined downward at angles of 20° and 5°, respectively, from the horizontal direction.

Among the four supplying nozzle tubes 10a to 10d and 10a′ to 10d′ on the respective side walls, as shown in FIG. 7B, the two supplying nozzle tubes 10c and 10d on the lower side of the side wall 2b′ and the two supplying nozzle tubes 10a′ and 10b′ on the upper side of the side wall 2c′ are first supplying nozzle tubes having a synchronized timing for supplying the treatment solution, and the two supplying nozzle tubes 10a and 10b on upper side of the side wall 2b′ and the two supplying nozzle tubes 10c′ and 10d′ on the lower side of the side wall 2c′ are second supplying nozzle tubes having a synchronized timing for supplying the treatment solution, thereby developing swirling currents in the inner bath 2. Specifically, for example, the treatment solution is first supplied from the second supplying nozzle tubes 10a, 10b, 10c′, and 10d′ simultaneously for a prescribed period of time so as to make a clockwise swirling current in the inner bath. After the prescribed period of time, the supply from the second supplying nozzle tubes is stopped, and the treatment solution is then supplied from the first supplying nozzle tubes 10c, 10d, 10a′, and 10b′ simultaneously so as to make a counterclockwise swirling current in the inner bath. By switching the above-described supplying nozzle tubes for a plurality of times, desirable treatment for the wafer W can be provided.

Furthermore, in the embodiment shown in FIG. 8, the two supplying nozzle tubes 10a and 10b on the upper side are inclined downward at angles of 45° and 40°, respectively, from the horizontal direction, and the two supplying nozzle tubes 10c and 10d on the lower side are inclined upward at angles of 40° and 45°, respectively, from the horizontal direction on one opposite side wall 2b′. In the same manner on the other opposite side wall 2c′, the two supplying nozzle tubes 10a′ and 10b′ on the upper side are inclined downward at angles of 45° and 40°, respectively, from the horizontal direction, and the two supplying nozzle tubes 10c′ and 10d′ on the lower side are inclined upward at angles of 40° and 45°, respectively, from the horizontal direction.

Among the four supplying nozzle tubes 10a to 10d and 10a′ to 10d′ on the respective side walls, as shown in FIG. 8, the two supplying nozzle tubes 10a and 10b on the upper side of the side wall 2b′ and the two supplying nozzle tubes 10c′ and 10d′ on the lower side of the side wall 2c′ are first supplying nozzle tubes having a synchronized timing for supplying the treatment solution, and the two supplying nozzle tubes 10c and 10d on lower side of the side wall 2b′ and the two supplying nozzle tubes 10a′ and 10b′ on the upper side of the side wall 2c′ are second supplying nozzle tubes having a synchronized timing for supplying the treatment solution, thereby developing swirling currents in the inner bath 2. Specifically, for example, the treatment solution is first supplied from the second supplying nozzle tubes 10c, 10d, 10a′, and 10b′ simultaneously for a prescribed period of time so as to make a clockwise swirling current in the inner bath. After the prescribed period of time, the supply from the second supplying nozzle tubes is stopped, and the treatment solution is then supplied from the first supplying nozzle tubes 10a, 10b, 10c′, and 10d′ simultaneously so as to make a counterclockwise swirling current in the inner bath. By switching the above-described supplying nozzle tubes for a plurality of times, desirable treatment for the wafer W can be provided with advantageous effects to prevent adhesion of particles.

It should be understood that the number of the supplying nozzle tubes and the angles at which their jetting ports are provided are not limited to the above-mentioned number and angles, and any numbers and angles can be selected.

1. A substrate treatment apparatus, comprising:
a treatment bath composed of a bottomed container which is surrounded by side walls on the four sides and is open at the top;
first and second supplying nozzle tubes which supply the treatment bath with a treatment solution,
the first and second supplying nozzle tubes being composed of hollow tube-shaped supplying nozzle tubes having a plurality of jetting ports arranged on one line at prescribed intervals on respective side plane thereof in the longitudinal direction, the jetting ports of the first supplying nozzle tubes being inclined diagonally downward at a prescribed angle from the horizontal direction, the jetting ports of the second supplying nozzle tubes being inclined diagonally upward at a prescribed angle from the horizontal direction, and the supplying nozzle tubes being arranged nearly horizontal to each other at prescribed intervals on one side wall plane of the treatment bath; and
a controller that controls switching of supply of the treatment solution alternatively from the first and second supplying nozzle tubes to the treatment bath at prescribed time intervals and makes swirling currents in different directions in the treatment bath,
the swirling currents being used for substrate surface treatment.

2. The substrate treatment apparatus according to claim 1, wherein the first and second supplying nozzle tubes are each composed of a plurality of supplying nozzle tubes and are alternatively placed at prescribed intervals.

3. The substrate treatment apparatus according to claim 1, wherein the first and second supplying nozzle tubes are each composed of a plurality of supplying nozzle tubes, the first supplying nozzle tubes are placed above, and the second supplying nozzle tubes are placed below a horizontal line running through a central part of a substrate to be treated placed upright in the treatment bath.

4. The substrate treatment apparatus according to claim 1, wherein the first and second supplying nozzle tubes are each composed of a plurality of supplying nozzle tubes, the first supplying nozzle tubes are placed below, and the second supplying nozzle tubes are placed above a horizontal line running through a central part of a substrate to be treated placed upright in the treatment bath.

5. The substrate treatment apparatus according to claim 1, wherein the first and second supplying nozzle tubes are provided to the outside of one side wall plane of the treatment bath and the plurality of jetting ports on the side plane are in communication with the inside of the treatment bath.

6. The substrate treatment apparatus according to claim 1, wherein the treatment bath includes an inner bath having a taller side wall provided with the first and second supplying nozzle tubes and shorter side walls, and an outer bath surrounding the inner bath so as to contain the treatment solution overflowed from the inner bath.

7. The substrate treatment apparatus according to claim 6, wherein each upper end surface of the shorter side walls is provided with a plurality of notches.

8. The substrate treatment apparatus according to any of claims 1 through 7, wherein the treatment bath is provided with an ultrasonic generator at an outer wall surface of a bottom wall thereof.

9. (canceled)

10. The substrate treatment apparatus according to claim 8, further comprising:
a controller that controls switching of supply of the treatment solution alternatively from the first and second supplying nozzle tubes to the treatment bath at prescribed time intervals, controls the ultrasonic generator, and makes swirling currents in different directions in the treatment bath,
and an appropriate combination of the swirling currents and ultrasonic waves generated by the ultrasonic generator being used for substrate surface treatment.

11. A substrate treatment apparatus, comprising:
a treatment bath composed of a bottomed container which is surrounded by side walls and is open at the top;
first and second supplying nozzle tubes which supply the treatment bath with a treatment solution,
the first and second supplying nozzle tubes being composed of hollow tube-shaped supplying nozzle tubes having a plurality of jetting ports arranged on at least one line at prescribed intervals on respective side plane thereof in the longitudinal direction, and are arranged nearly horizontal to each other at prescribed intervals on each of both opposite side wall planes of the treatment bath, the jetting ports of the first and second supplying nozzle tubes provided on one of the opposite side wall planes being inclined diagonally downward and upward, respectively, at a prescribed angle from the horizontal direction, and the jetting ports of the first and second supplying nozzle tubes provided on the other of the opposite side wall planes being inclined diagonally upward and downward, respectively, at a prescribed angle from the horizontal direction; and
a controller that controls switching of supply of the treatment solution alternatively from the first and second supplying nozzle tubes to the treatment bath at prescribed time intervals and makes swirling currents in different directions in the treatment bath,
the swirling currents being used for substrate surface treatment.

12. The substrate treatment apparatus according to claim 11, wherein the first and second supplying nozzle tubes are each composed of a plurality of supplying nozzle tubes and are alternatively placed at prescribed intervals.

13. The substrate treatment apparatus according to claim 11, wherein the first and second supplying nozzle tubes are each composed of a plurality of supplying nozzle tubes, the first supplying nozzle tubes are placed above and below a horizontal line running through a central part of a substrate to be treated placed upright in the treatment bath on one and the other sides, respectively, and the second supplying nozzle tubes are placed below and above the horizontal line on one and the other sides, respectively.

14. The substrate treatment apparatus according to claim 11, wherein the first and second supplying nozzle tubes are each composed of a plurality of supplying nozzle tubes, the first supplying nozzle tubes are placed below and above a horizontal line running through a central part of a substrate to be treated placed upright in the treatment bath on one and the other sides, respectively, and the second supplying nozzle tubes are placed above and below the horizontal line on one and the other sides, respectively.

15. The substrate treatment apparatus according to claim 11, wherein the first and second supplying nozzle tubes are provided to the outside of both opposite side wall planes of the treatment bath and the plurality of jetting ports on the side plane are in communication with the inside of the treatment bath.

16. The substrate treatment apparatus according to claim 11, wherein the treatment bath includes an inner bath containing a substrate to be treated and an outer bath surrounding the inner bath so as to contain the treatment solution overflowed from the inner bath, and each upper end surface of the inner bath is provided with a plurality of notches.

17. The substrate treatment apparatus according to any of claims 11 through 16, wherein the treatment bath is provided with an ultrasonic generator at an outer wall surface of a bottom wall thereof.

18. (canceled)

19. The substrate treatment apparatus according to claim 17, further comprising:
a controller that controls switching of supply of the treatment solution alternatively from the first and second supplying nozzle tubes to the treatment bath at prescribed time intervals, controls the ultrasonic generator, and makes swirling currents in different directions in the treatment bath,
an appropriate combination of the swirling currents and ultrasonic waves generated by the ultrasonic generator being used for substrate surface treatment.
